(19) United States
(12) Patent Application Publication
(10) Pub. No.: US 2010/0091465 A1
(43) Pub. Date: Apr. 15, 2010

(54) APPARATUS AND METHOD FOR IMPROVING CUSTOMER RETENTION

(75) Inventors: Mike Roberts, Overland Park, KS (US); Jeffrey Stafford, Overland Park, KS (US); Tony Dandridge, Raymore, MO (US)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: EMBARQ HOLDINGS COMPANY, LLC

(21) Appl. No.: 12/250,066

(22) Filed: Oct. 13, 2008

(51) Int. Cl. H05K 7/00; G06Q 30/00

(52) U.S. Cl. 361/728; 29/592.1; 705/34; 705/14.3

(57) ABSTRACT

The disclosed embodiments provide an apparatus and method for improving customer retention. In accordance with one embodiment, a telecommunication device comprising a chassis that includes features for operating the telecommunication device and a display module removably coupled to the chassis is presented. The chassis is compatible with different display modules. Thus, the disclosed embodiments enable a telecom customer to upgrade a telecommunication device at minimal cost, thereby, improving customer retention.

### BACKGROUND OF THE INVENTION

1. Field of the Invention

The principles of the present invention relate to telecommunications, and more specifically, to improving customer retention by providing a modular customer premise equipment/telecommunication device.

2. Description of the Related Art

A customer premise equipment (CPE) is service provider equipment, such as, but not limited to, to telephones that are located on the customer's premises (i.e., physical location) rather than on the provider's premises or in between. Acquiring customer premise equipment, such as IP phones and analog phones, is a large investment for a company. When a company outgrows its existing telephone system, either as a result of the company increasing in size or as a result in the technology becoming outdated, the company must invest in an entirely new telephone system. For a telephone system provider, a customer's need to reinvest in a new telephone system provides an opportunity for the sale of a new system. However, the provider's competitors are afforded the same opportunity of selling a new system. In order to retain customers, the disclosed embodiments recognize that it would be beneficial to provide a telecommunication device, such as, but not limited to, a telephone that can be upgraded at a lower cost rather than replacing the entire system. Further, by replacing only a part of the telecommunication device, the environmental impact is reduced because fewer parts end up in the landfills.

### SUMMARY

The disclosed embodiments provide an apparatus and method for improving customer retention. In accordance with one embodiment, a telecommunication device comprising a chassis that includes features for operating the telecommunication device and a display module removably coupled to the chassis is presented. The chassis is compatible with different display modules. Thus, the disclosed embodiments enable a telecom customer to upgrade a telecommunication device at minimal cost, thereby, improving customer retention.

### BRIEF DESCRIPTION OF THE DRAWINGS

For a more complete understanding of the present application, the objects and advantages thereof, reference is now made to the following descriptions taken in conjunction with the accompanying drawings, in which:

FIG. 1 depicts an embodiment of a telecommunication device having a chassis and a display module that is removably coupled to the chassis;

FIG. 2 depicts an embodiment of the display module being removed from the chassis;

FIG. 3 depicts an embodiment of a mechanism for coupling and/or removing the display module from the chassis;

FIG. 4 depicts an embodiment of embodiments of different display modules that are couplable to the chassis;

FIG. 5 depicts an embodiment of connecting a different display module to the chassis;

FIG. 6 depicts an embodiment of the telecommunication device with the different display module coupled to the chassis; and

FIG. 7 depicts an embodiment of a process for improving customer retention.

### DETAILED DESCRIPTION OF THE DRAWINGS

Almost all customer premise equipment is built on the same chassis with the only differentiator being the screen resolution and number of call appearances (or lines). The disclosed embodiments provide a customer with a modular CPE/telecommunication device that grows as the company grows. More particularly, in one embodiment, a telecommunication device is provided that includes a chassis and a display module that is coupled to the chassis. The display module is interchangeable with an upgraded and/or different display module.

In general, the upgraded display module may possess newer technology than a prior display module. Even if a company has not outgrown or undergone any major changes, the company may still desire to upgrade the company's telecommunication system in order to benefit from technological advancements in the telecommunications field.

In some embodiments, the upgraded display module may have a higher screen resolution than a prior display module. For example, the upgraded display module may possess a greater number of pixels on the display than a prior display module. Additionally or alternatively, the display of the upgraded display module may possess a greater number of colors than a prior display module. As another feature, the upgraded display module may possess video phone capability by incorporating a camera into the upgraded display module.

The upgraded display module may also be tailored to meet the needs of a company's expanded growth and/or enhanced sophistication. In certain embodiments, the upgraded display module may support a greater number of users and/or greater number of telephone lines than a prior display module.

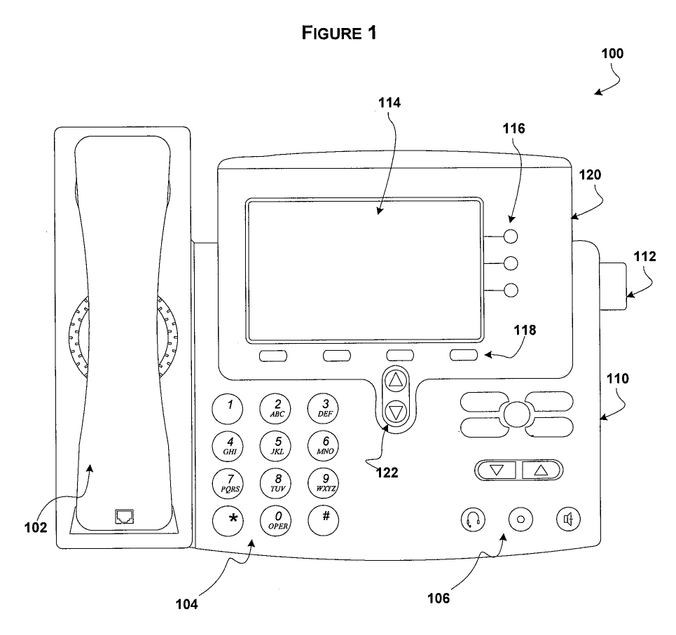

The disclosed embodiments and advantages thereof are best understood by referring to FIGS. 1-6 of the drawings, like numerals being used for like and corresponding parts of the various drawings. Other apparatus features and advantages of the disclosed embodiments will be or will become apparent to one of ordinary skill in the art upon examination of the following figures and detailed description. It is intended that all such additional apparatus, features and advantages be included within this description, be within the scope of the disclosed embodiments, and be protected by the accompanying drawings.

With reference now to FIG. 1, an embodiment of a telecommunication device 100 having a chassis 110 and an interchangeable display module 120 is presented. Telecommunication device 100 may be any type of telecommunication device, such as, but not limited to, a standard landline telephone, a cellular phone, and/or a network voice over IP (VOIP) phone.

In some embodiments, chassis 110 includes one or more components and/or features associated with operating telecommunication device 100. For example, in one embodiment, telecommunication device 100 includes a handset receiver 102, a dial pad 104, and miscellaneous control features 106, such as, but not limited to, volume control, speakerphone, and a messages and/or contacts button. Additionally, in some embodiments, chassis 110 includes a release button 112 for enabling the removal of display module 120 from chassis 110. Release button 112 may be a push button, a slidable release/locking mechanism, and/or any other type of mechanism for releasing display module 120 from chassis 110. Further, in some embodiments, release button 112 may be found on display module 120. Moreover, in other embodiments, display module 120 may be removed from chassis 110 simply by pushing display module 120 away from chassis 110 without the use of a releasing mechanism.

In the disclosed embodiment, display module 120 includes a display 114, one or more line or speed dial buttons 116, soft keys 118, and navigation button 122. In some embodiments, display 114 is a liquid-crystal display (LCD) screen. Further, in some embodiments, display 114 displays a user interface that includes features, such as, but not limited to, the time, date, phone number, caller ID, line/call status and soft key tabs. Additionally, in some embodiments, display 114 includes touch screen capabilities to enable to a user to select options/features presented on display 114 by touching display 114 in the respective location.

Line or speed dial buttons 116 open a new line, speed dials a number on display 114, or ends a call. In the depicted embodiment, display module 120 has three line/speed dial buttons 116. As will be further described, in one embodiment, a consumer may update telecommunication device 100 with a different display module having a different number of line/speed dial buttons 116.

Soft keys 118 are one or more buttons, located alongside display 114, which enables a user to engage any of the functions (i.e., soft keys) displayed on the corresponding tabs displayed on display 114. In some embodiments, the displayed soft keys may change depending on the status of telecommunication device 100.

Navigation button 122 enables a user to scroll through text and/or select features displayed on the display module 120. In some embodiments, navigation button 120 may include four way navigational features to enable vertical and horizontal scrolling.

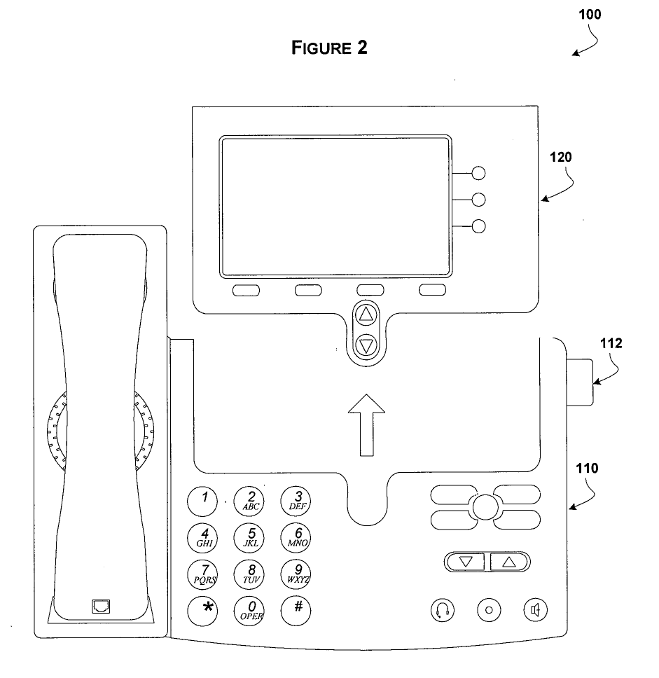

FIG. 2 depicts display module 120 being removed from chassis 110. As previously described, in one embodiment, a user must push release button 112 to disable a locking mechanism, such as, but not limited to, releasing a locking hinge coupling display module 120 to chassis 110.

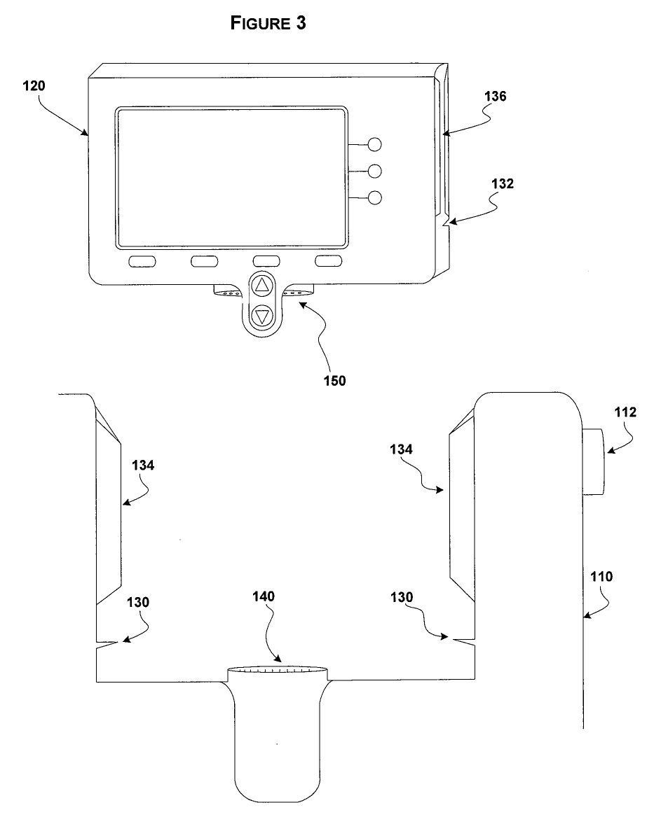

For example, as shown in FIG. 3, in some embodiments, chassis 110 may include locking hinges 130. In one embodiment, locking hinges 130 slides in and out of chassis 110. For instance, in one embodiment, when release button 112 is depressed, locking hinges 130 slide completely within chassis 110 to enable display module 120 to be removed from chassis 110. When release button 112 is not depressed, locking hinges 130 slide out to engage notches 132 on display module 120 to lock display module 120 into place. In other embodiments, locking hinges 130 may flip vertically when release button 112 is depressed to enable the release of display module 120.

In some embodiments, chassis 110 may include one or more alignment guides 134 for properly aligning display module 120 into chassis 110. For example, in some embodiments, display module 120 may include alignment grooves 136 for engaging alignment guides 134 on chassis 110.

In addition, in some embodiments, chassis 110 may include a connector 140 for coupling chassis 110 with a connector 150 on display module 120. Connectors 140 and 150 may be any type of connector capable of electrically coupling chassis 110 to display module 120. For example, in some embodiments, display module 120 includes a female connector, such as, but not limited to, one of the many different types of small computer system interface (SCSI) connectors, and chassis 110 includes the corresponding male connector and/or vice versa. In other embodiments, chassis 110 and display module 120 may be coupled using a universal serial bus (USB) connection.

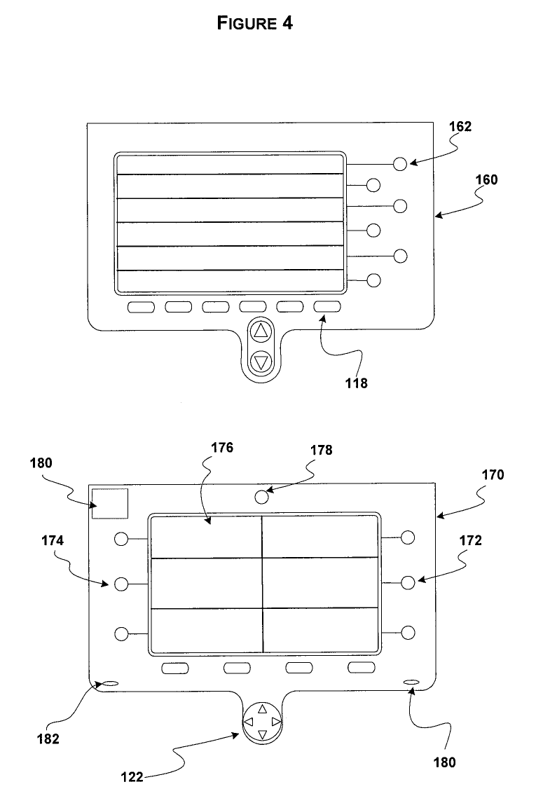

With reference now to FIG. 4, different embodiments of display modules that may be interchanged with display module 120 and coupled to chassis 110 are presented. For example, in FIG. 4, display module 160 and display module 170 are presented. Display modules 160 and 170 are intended to be illustrative examples and are not intended to imply a particular limitation and/or feature of the disclosed embodiments.

In the depicted embodiment, display module 160 includes six lines or speed dial buttons 162 for selecting a new line and/or an option/feature associated with the respective button as opposed to the three lines and/or speed dial buttons 116 as indicated in display module 120. Further, in some embodiments, display module 160 may provide an improved screen resolution over display module 120. Additionally, in some embodiments, display module 160 may provide additional color capabilities over display module 120. For example, in some embodiments, a consumer may upgrade from a black and white screen to a color screen. Of course, in some embodiments, display module 160 includes similar features as display module 120, such as, but not limited to, soft keys 118 and navigation button 122. However, in some embodiments, display module 160 may include additional soft keys 118, as depicted in display module 160.

Display module 170 depicts another embodiment of a display module that may be coupled to chassis 110. In the depicted embodiment, display module 170 includes three lines and/or speed dial buttons 172 located on one side and three lines and/or speed dial buttons 174 located on the other side. This particular configuration enables viewing and selecting menu option/feature items on a double column user interface display 176. In addition, in some embodiments, navigation button 122 may be circular to enable scrolling in all directions of items displayed by interface display 176. In some embodiments, display module 170 may include a camera 178 to for providing video phone capabilities.

Further, in some embodiments, display module 170 may be operable to function as a telecommunication device (e.g., make and receive calls) independent of chassis 110. For example, in some embodiments, display module 170 may include a separate power source (not depicted), such as, but not limited to, an internal rechargeable battery. Alternatively, in some embodiments, display module 170 may use disposable batteries and/or any other known power source.

Additionally, in some embodiments, display module 170 may include a wireless communication device 180, such as, but not limited to, a wireless Bluetooth® device capable of communicating with a wireless Bluetooth® headset. In addition, communication device 180 may include Wi-Fi capabilities. In these embodiments, a user may make/receive calls by using voice activation/recognition, entering a number using a touch screen keypad, and/or selecting a number displayed on display module 170, such as, but not limited to, a speed dial number or a number associated with user's contacts list stored in memory located within display module 170. In some embodiments, communication device 180 connects wirelessly to the Internet and using voice over IP technology, enables a user to make/receive calls. In addition, in some embodiments, display module 170 may include a microphone 182 and a speaker 184 to enable a user to communicate directly with display module 170 without the use of a headset.

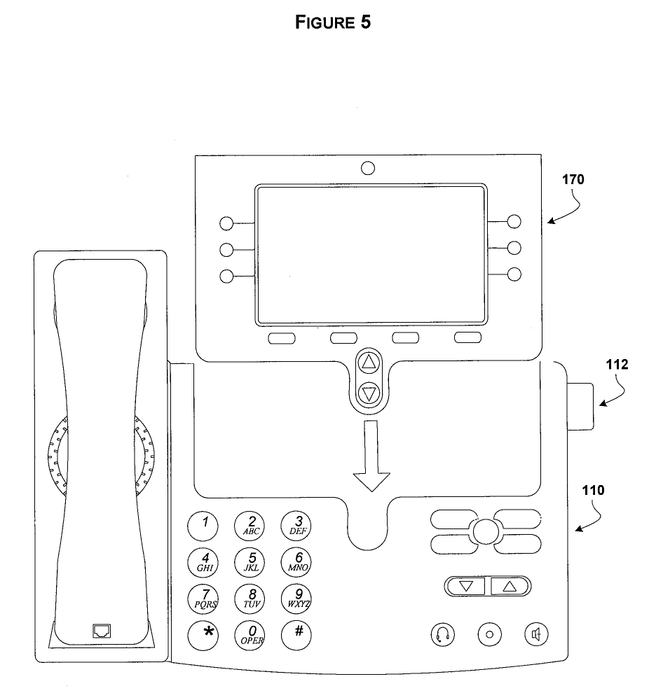

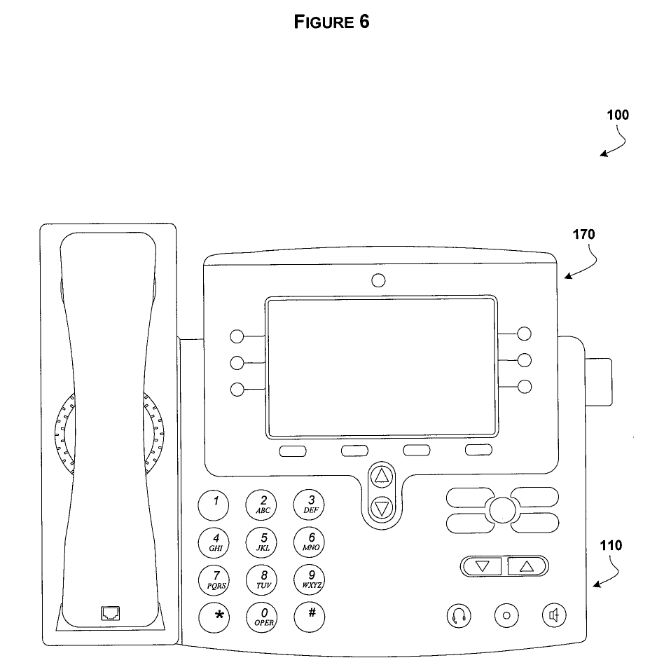

FIG. 5 depicts connecting display module 170 to chassis 110. As previously described, in some embodiments, a user aligns alignment grooves 136 on display module 170 with alignment guides 134 on chassis 110. In addition, in some embodiments, the user depresses release button 112 to retract locking hinges 130 to enable display module 170 to slide into chassis 110. Further, in some embodiments, when locking hinges 130 on chassis 110 engage notches 132 on display module 170, chassis 110 and display module 170 are properly coupled as depicted in FIG. 6.

Accordingly, the disclosed embodiments, present a modular telecommunication device, such as, but not limited to, a telephone, comprising of a chassis that includes features for operating the telecommunication device and a display module removably coupled to the chassis. The display module and/or chassis may be interchanged with other like components, such as, but not limited to, when an upgraded display module with newer technology becomes available and/or when the needs of a telecommunication customer changes and/or when one of the components malfunctions.

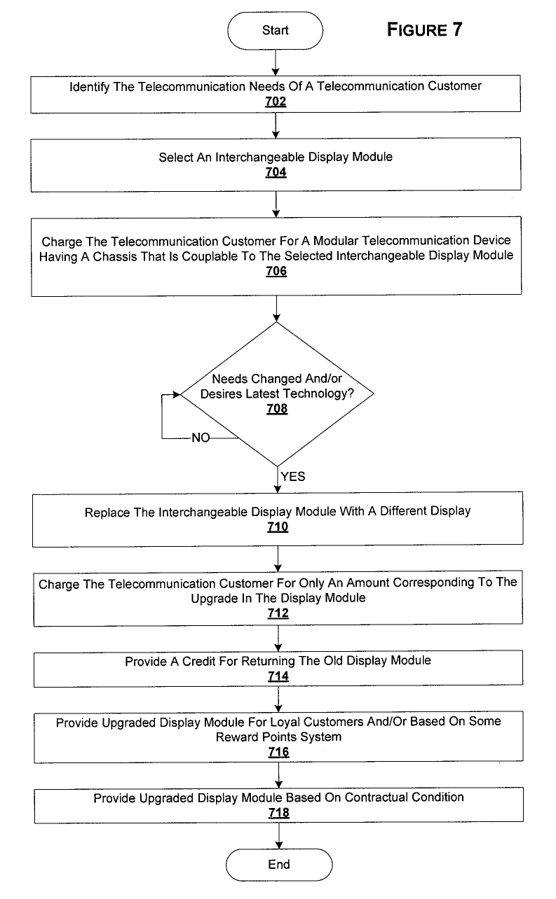

As a result, the disclosed embodiments improve customer retention by enabling a telecommunication customer to upgrade a telecommunication device at a minimal cost. For example, in one embodiment, as depicted in FIG. 7, a service provider and/or telecommunication customer may identify the telecommunication needs of a telecommunication customer at step 702. Based on the identified telecommunication needs of the telecommunication customer, an interchangeable display module is selected at step 704. At step 706, the service provider charges the telecommunication customer for a modular telecommunication device having a chassis that is couplable to the selected interchangeable display module. At a later date, if the telecommunication needs of the telecommunication customer changes and/or the telecommunication customer desires the latest technology at step 708, the telecommunication customer may simply replace the interchangeable display module with a different display module provided by the service provider at step 710. At step 712, the service provider charges the telecommunication customer for only the amount corresponding to the upgrade in the display module. In addition, in some embodiments, the service provider may provide a credit for returning the old display module at step 714. Thus, the telecommunication customer has upgraded his telecommunication device at a lower cost than having to replace the entire system. Therefore, the disclosed embodiments improve customer retention.

Alternatively, in some embodiments, a service provider may reward loyal customers with an upgraded display module at step 716 and/or the telecommunication customer may receive an upgraded display module based a contractual condition between the telecommunication service provider and the telecommunication customer at step 718 (e.g., new upgrades every two years and/or new upgrades if usage charges exceed a specified amount, etc...). Further, improving customer retention. Moreover, the disclosed embodiments are environmentally friendly because less waste is produced from replacing old telecommunication systems, thus, companies that are concerned about the environment are more likely to remain with the same service provider and use the disclosed embodiments.

What is claimed:

1. A telecommunication device comprising:
a chassis that includes features for operating the telecommunication device; and
a display module removably coupled to the chassis.

2. The telecommunication device of claim 1, wherein the display module may be interchanged with a different display module.

3. The telecommunication device of claim 1, wherein the chassis may be interchanged with a different chassis.

4. The telecommunication device of claim 1, wherein the chassis includes a releasing mechanism to enable decoupling of the display module from the chassis.

5. The telecommunication device of claim 1, wherein the chassis includes a mechanism for electrically coupling the display module with the chassis.

6. The telecommunication device of claim 1, wherein the chassis includes an alignment mechanism for aligning the display module with the chassis.

7. The telecommunication device of claim 1, wherein the display module possesses touch screen technology.

8. The telecommunication device of claim 1, wherein the display module may be interchanged with a different display module that supports a greater number of telephone lines than the display module.

9. The telecommunication device of claim 1, wherein the display module may be interchanged with a different display module having a higher screen resolution than the display module.

10. The telecommunication device of claim 1, wherein the display module has a camera for providing video phone capabilities.

11. The telecommunication device of claim 1, wherein the interchangeable display module includes a wireless communication device.

12. The telecommunication device of claim 1, wherein the interchangeable display module includes a power source and is operable to function as a telecommunication device independent of the chassis.

13. A method for improving customer retention, the method comprising:
identifying the telecommunication needs of a telecommunication customer;
selecting an interchangeable display module based on the identified telecommunication needs of the telecommunication customer;
charging the telecommunication customer for a modular telecommunication device having a chassis that is couplable to the interchangeable display module; and
responsive to the telecommunication customer changing the interchangeable display module to a different display module, charging the telecommunication customer for only an amount corresponding to the different display module.

14. The method of claim 13, further comprising providing a credit to the telecommunication customer for returning the interchangeable display module.

15. The method of claim 13, further comprising replacing the interchangeable display module with a different display module in response to a change in the telecommunication needs of the telecommunication customer.

16. The method of claim 13, further comprising replacing the interchangeable display module with an upgraded display module in response to a change in technology.

17. The method of claim 13, further comprising replacing the interchangeable display module with an upgraded display module as a reward for the telecommunication customer being a loyal customer.

18. The method of claim 13, further comprising replacing the interchangeable display module with an upgraded display module after the telecommunication customer acquires an adequate number of reward points.

19. The method of claim 13, further comprising replacing the interchangeable display module with an upgraded display module based on a contractual condition between a telecommunication service provider and the telecommunication customer.

20. A method for manufacturing a telecommunication device, the method comprising:
producing a chassis that includes features for operating the telecommunication device; and
producing a display module removably coupled to the chassis.
